(19) United States
(12) Patent Application Publication
(10) Pub. No.: US 2024/0242960 A1
(43) Pub. Date: Jul. 18, 2024

(54) INFORMATION PROCESSING DEVICE AND INFORMATION PROCESSING METHOD

(71) Applicant: EBARA CORPORATION, Tokyo (JP)

(72) Inventor: MITSUNORI SUGIYAMA, Tokyo (JP)

(73) Assignee: EBARA CORPORATION, Tokyo (JP)

(21) Appl. No.: 18/515,265

(22) Filed: Nov. 21, 2023

(30) Foreign Application Priority Data
Jan. 16, 2023 (JP) 2023-004722

(51) Int. Cl. H01L 21/02; H01L 21/67

(52) U.S. Cl. CPC H01L 21/02024; H01L 21/67253

(57) ABSTRACT

An information processing device 3A includes: a calculation processing part 301, calculating start timings of respective processes when the respective processes are performed in order on a predetermined number of wafers W in a substrate processing device 2; an event reception part 302, receiving event information indicating an occurrence situation of an event affecting execution of any of the respective processes; and a re-calculation part 303, re-calculating the start timings of the respective processes based on the occurrence situation of the event indicated in the event information when the event information is received by the event reception part 302 during execution of the respective processes by the substrate processing device 2 in accordance with the start timings of the respective processes calculated by the calculation processing part.

### CROSS-REFERENCE TO RELATED APPLICATION

This application claims the priority benefit of Japan application no. 2023-004722, filed on Jan. 16, 2023. The entirety of the above-mentioned patent application is hereby incorporated by reference herein and made a part of this specification.

### BACKGROUND

### Technical Field

The invention relates to an information processing device and an information processing method.

### Description of Related Art

As one of the substrate processing devices performing various processes on a substrate, such as a semiconductor wafer, a substrate processing device performing chemical mechanical polishing (CMP) is known. Such substrate processing device includes, for example, a polishing unit performing a polishing process on the substrate, a finishing unit performing a finishing process (e.g., a cleaning process or a drying process) on the substrate after the polishing process, and a transport unit performing a transport process that transports the substrate among the units, and is configured to execute a series of processes by operating the respective units in order (see, for example, Patent Document 1).

### PRIOR ART DOCUMENT(S)

### Patent Document(s)

[Patent Document 1] Japanese Laid-open No. 2004-265906

In order to facilitate processing efficiency, a substrate processing device is configured to include multiple polishing units, multiple finishing units, and multiple transport units. Therefore, in the substrate processing device, in the case where automatic operation is performed so that the respective units are operated in order by using a predetermined number of substrates as processing targets, a calculation process is performed to plan (optimize) in advance the start timings of the respective processes, thereby making the time at which the respective processes on all the substrates end the shortest. In addition, by operating the respective units in order in accordance with the calculation result of the calculation process, the substrate processing device can reduce the standby time of the respective units, and the processing efficiency of the entire substrate processing device can be facilitated.

However, at the time of actual automatic operation, for example, due to the occurrence of various events resulting from the state of the substrate processing device, the state of a substrate, an operation of the user, etc., the respective processes may not be performed according to the schedule set in advance. Therefore, in the case where the respective units are operated in accordance with the schedule set in advance regardless of the situation that various events occur during automatic operation, the processing efficiency of the substrate processing device may deteriorate.

The invention provides an information processing device and an information processing method capable of suppressing the deterioration of the processing efficiency of the substrate processing device even in the case where various events occur during automatic operation.

### SUMMARY

An aspect of the invention provides an information processing device. The information processing device includes: a calculation processing part, calculating start timings of respective processes when the respective processes are performed in order on a predetermined number of substrates in a substrate processing device, the substrate processing device including: multiple polishing units performing a polishing process on the substrates in parallel; multiple finishing units, performing a finishing process on the substrates after the polishing process in a finishing processing order; and multiple transport units, performing a transport process for transporting the substrates; an event reception part, receiving event information indicating an occurrence situation of an event affecting execution of any of the respective processes; and a re-calculation part, re-calculating the start timings of the respective processes based on the occurrence situation of the event indicated in the event information when the event information is received by the event reception part during execution of the respective processes by the substrate processing device in accordance with the start timings of the respective processes calculated by the calculation processing part.

Another aspect of the invention provides an information processing method. The information processing method includes: a calculation processing process, calculating start timings of respective processes when the respective processes are performed in order on a predetermined number of substrates in a substrate processing device, the substrate processing device including: multiple polishing units performing a polishing process on the substrates in parallel; multiple finishing units, performing a finishing process on the substrates after the polishing process in a finishing processing order; and multiple transport units, performing a transport process for transporting the substrates; an event reception process, receiving event information indicating an occurrence situation of an event affecting execution of any of the respective processes; and a re-calculation process, re-calculating the start timings of the respective processes based on the occurrence situation of the event indicated in the event information when the event information is received by the event reception process during execution of the respective processes by the substrate processing device in accordance with the start timings of the respective processes calculated by the calculation processing process.

Issues, configurations, and effects other than those described above will be made clear in the detailed description of the invention described below.

### BRIEF DESCRIPTION OF THE DRAWINGS

FIG. 1 is a view illustrating an overall configuration of an example of a substrate processing system 1.

FIG. 2 is a schematic plan view illustrating an example of a substrate processing device 2.

FIG. 3 is a perspective view illustrating an example of first and second polishing units 22A, 22B.

FIG. 4 is a perspective view illustrating an example of a first finishing unit 23A performing a roll sponge cleaning process.

FIG. 5 is a perspective view illustrating an example of a second finishing unit 23B performing a pen sponge cleaning process.

FIG. 6 is a perspective view illustrating an example of a third finishing unit 23C performing a drying process.

FIG. 7 is a block diagram illustrating an example of the substrate processing device 2.

FIG. 8 is a view illustrating a hardware configuration of an example of a computer 900.

FIG. 9 is a block diagram illustrating an example of an information processing device 3A according to a first embodiment.

FIG. 10 is a functional diagram illustrating an example of the information processing device 3A according to the first embodiment.

FIG. 11 is a diagram illustrating an example of an initial substrate processing schedule 13A.

FIG. 12 is a diagram illustrating an example of a substrate processing schedule 13B generated when rework event information is received.

FIG. 13 is a diagram illustrating an example of a substrate processing schedule 13C generated by a re-calculation processing part 303 when hot lot event information is received.

FIG. 14 is a diagram illustrating an example of a substrate processing schedule 13D generated by the re-calculation processing part 303 when unit arrival event information is received.

FIG. 15 is a diagram illustrating an example of a substrate processing schedule 13E generated by the re-calculation processing part 303 when unit failure event information is received.

FIG. 16 is a diagram illustrating an example of a substrate processing schedule 13F generated by the re-calculation processing part 303 when unit failure event information is received.

FIG. 17 is a diagram illustrating an example of a substrate processing schedule 13G generated by the re-calculation processing part 303 when recipe change event information is received.

FIG. 18 is a flowchart illustrating an example of an information processing method performed by the information processing device 3A according to the first embodiment.

FIG. 19 is a block diagram illustrating an example of an information processing device 3B according to a second embodiment.

FIG. 20 is a functional diagram illustrating an example of the information processing device 3B according to the second embodiment.

FIG. 21 is a flowchart illustrating an example of an information processing method performed by the information processing device 3B according to the second embodiment.

### DESCRIPTION OF THE EMBODIMENTS

According to the information processing device according to an aspect of the invention, when the event information is received during the execution of the respective processes by the substrate processing device in accordance with the start timings of the respective processes calculated by the calculation processing part, the re-calculation processing part re-calculates the start timings of the respective processes based on the occurrence situation of the event indicated in the event information. Therefore, since the start timings of the respective processes are re-calculated based on the occurrence situation of the event, the processing efficiency of the substrate processing device can be suppressed from deteriorating even in the case where various events occur during automatic operation.

Embodiments for carrying out the invention will be described below with reference to the drawings. In the following, the scope necessary for the description for achieving the objective of the invention will be schematically shown, the scope necessary for explaining relevant portions of the invention will be mainly explained, and parts where explanation is omitted shall be based on conventional techniques.

### First Embodiment

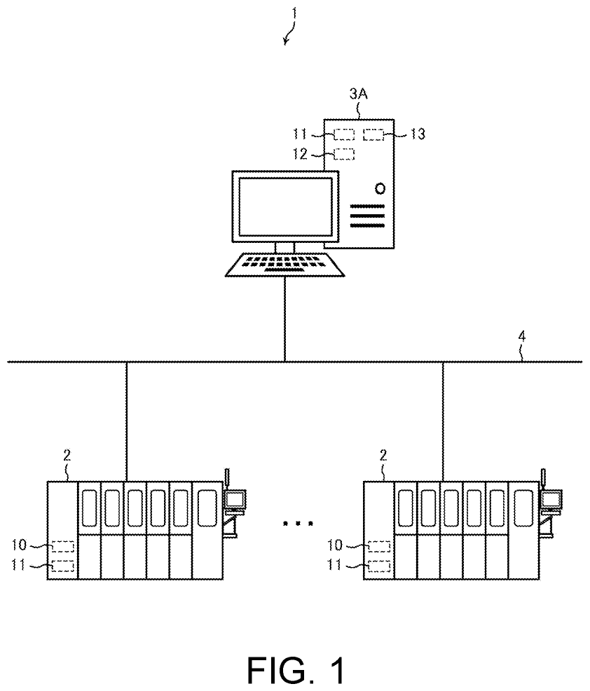

FIG. 1 is a view illustrating an overall configuration of an example of a substrate processing system 1. The substrate processing system 1 according to the embodiment mainly includes a substrate processing device 2 and an information processing device 3A, and is configured to be connected with a wired or wireless network 4 to be able to transmit and receive various data with respect to each other. The quantities of the substrate processing device 2 and the information processing device 3A and the connection configuration of the network 4 are not limited to the example of FIG. 1, but may be modified as appropriate.

The substrate processing device 2 includes multiple processing units (details will be described subsequently) performing various processes on a substrate (referred to as “wafer” in the following) W, such as a semiconductor wafer. The substrate processing device 2 is a device performing a chemical mechanical polishing process (referred to as “polishing process” in the following), a finishing process, a transport process, etc., on the wafer W by operating the respective processing units. At this time, the substrate processing device 2 executes the respective processes in accordance with a substrate processing schedule generated by the information processing device 3A while referring to device setting information 10 formed by multiple device parameters set to the respective processing units and substrate recipe information 11 determining operations of the polishing process and the finishing process.

The information processing device 3A, for example, is configured by a server-type or a cloud-type device, and cooperates with the substrate processing device 2 or a user terminal device (not shown) to operate. The information processing device 3A, for example, generates a substrate processing schedule 13 by calculating the start timings of the respective processes when the respective processes are performed in order on a predetermined number of the wafers W in the substrate processing device 2 based on, for example, the substrate recipe information 11 or the processing time information 12 indicating the processing time required for each process. In addition, at the time when an event that affects the execution of any of the respective processes occurs when the substrate processing device 2 performs the respective processes according to the substrate processing schedule 13, the information processing device 3A re-calculates the start timings of the respective processes and updates the substrate processing schedule 13 based on the result of re-calculation. In addition, the information processing device 3A controls the operations of the respective processing units by instructing the substrate processing device 2 the start timings of the respective processes based on the substrate processing schedule 13.

### Substrate Processing Device

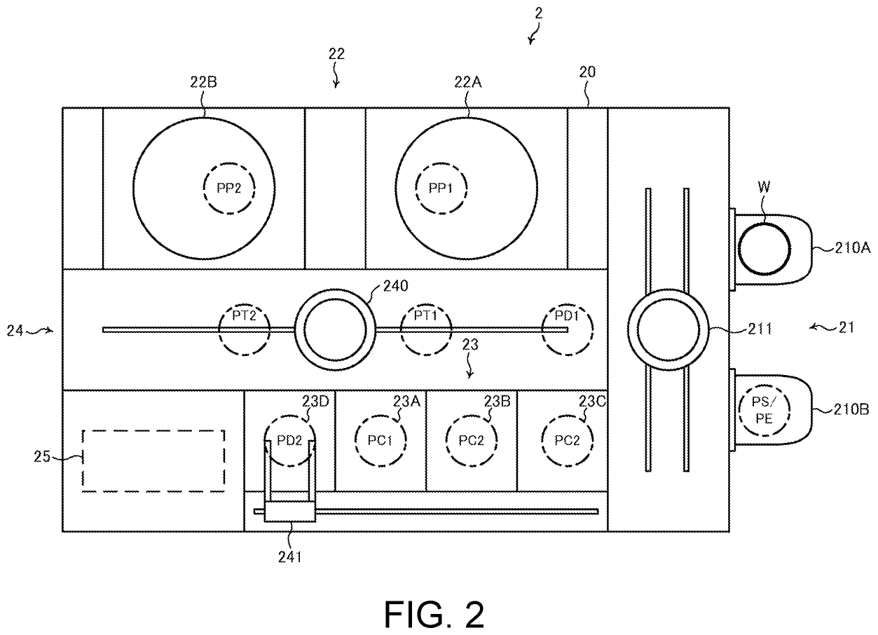

FIG. 2 is a schematic plan view illustrating an example of the substrate processing device 2. The substrate processing device 2 is configured by including, in a housing 20 having a substantially rectangular shape when viewed in a plan view, a load/unload part 21, a polishing part 22, a finishing part 23, a substrate transport part 24, and a control unit 25.

### Load/Unload Part

The load/unload part 21 includes first and second front load parts 210A, 210B and a load/unload robot 211. In the first and second front load parts 210A, 210B, wafer cassettes (an FOUP, etc.,) able to accommodate multiple wafers W in the upper-lower direction are mounted. The load/unload robot 211, as a transport unit, is movable along the direction in which the wafers W accommodated in the wafer cassettes are accommodated (upper-lower direction) and a direction in which the first and second front load parts 210A, 210B are arranged (the lateral direction of the housing 20).

The load/unload robot 211 is configured to be accessible to a substrate load position PS, a first substrate delivery position PD1, the finishing part 23 (specifically, a finishing unit 23C in the most downstream process to be described subsequently), and a substrate unload position PE. The load/unload robot 211 includes two hands (not shown), i.e., upper and lower hands, for delivering the wafer W. The lower hand is used at the time of delivering the wafer W before processing, and the upper hand is used at the time of delivering the wafer W after processing.

The substrate load position PS and the substrate unload position PE are the positions of the wafer cassettes respectively mounted in the first and second front load parts 210A, 210B. As a transport process of the wafer W, the load/unload robot 211 performs a load process in which the wafer W is loaded to the first substrate delivery position PD1 from the wafer cassette as the substrate load position PS and an unload process in which the wafer W after the finishing process is unloaded to the wafer cassette as the substrate unload position PE from the finishing part 23. The substrate load position PS and the substrate unload position PE may be the same or different positions.

### Polishing Part

The polishing part 22 includes multiple (two, in the embodiment) polishing units 22A, 22B respectively performing the polishing process on the wafer W. In the embodiment, the first and second polishing units 22A, 22B are arranged and disposed along the longitudinal direction of the housing 20, and perform the polishing process in parallel.

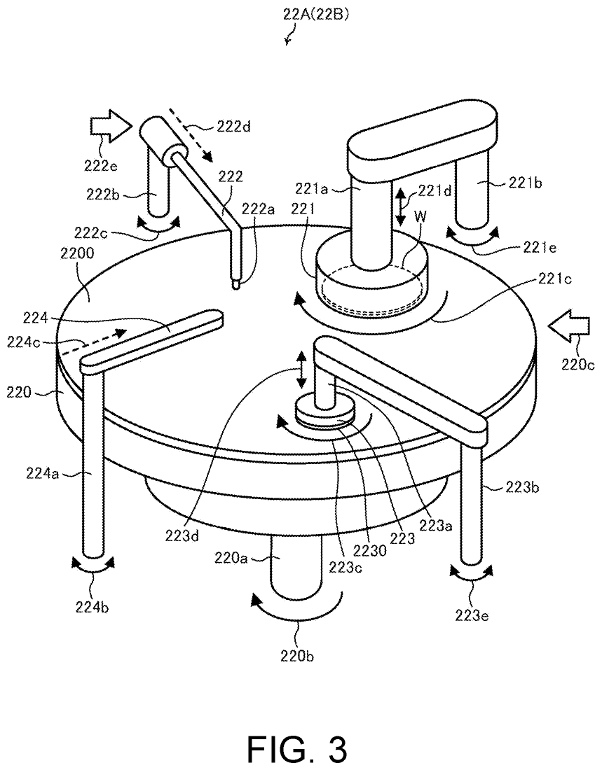

FIG. 3 is a perspective view illustrating an example of the first and second polishing units 22A, 22B. In the embodiment, the first and second polishing units 22A, 22B are described as components sharing basic configurations or functions.

Each of the first and second polishing units 22A, 22B includes a polishing table 220, a top ring (substrate holding part 221), a polishing fluid supply part 222, a dresser 223, and an atomizer 224. The polishing table 220 rotatably supports a polishing pad 2200 having a polishing surface. The top ring (substrate holding part) 221 rotatably holds the wafer W and polishes the wafer W while pressing the wafer W against the polishing pad 2200 on the polishing table 220. The polishing fluid supply part 222 supplies a polishing fluid to the polishing pad 2200. The dresser 223 rotatably supports a dresser disk 2230 and brings the dresser disk 2230 into contact with the polishing surface of the polishing pad 2200 to dress the polishing pad 2200. The atomizer 224 injects a cleaning fluid to the polishing pad 2200.

The polishing table 220 includes a rotary movement mechanism part 220b and a temperature adjustment mechanism part 220c. The rotary movement mechanism part 220b is supported by a polishing table shaft 220a and rotatably drives the polishing table 220 about the axis center thereof. The temperature regulation mechanism part 220c regulates the surface temperature of the polishing pad 2200.

The top ring 221 includes a rotary movement mechanism part 221c, a vertical movement mechanism part 221d, and a swing movement mechanism part 221e. The rotary movement mechanism part 221c is supported by a top ring shaft 221a movable in the upper-lower direction, and rotatably drives the top ring 221 about the axis center thereof. The vertical movement mechanism 221d moves the top ring 221 in the upper-lower direction. The swing movement mechanism part 221e turnably (swingably) moves the top ring 221 with the support shaft 221b as the turning center. The rotary movement mechanism part 221c, the vertical movement mechanism part 221d, and the swing movement mechanism part 221e function as a substrate movement mechanism part that moves relative positions of the polishing pad 2200 and the polished surface of the wafer W.

The polishing fluid supply part 222 includes a polishing fluid supply nozzle 222a, a swing movement mechanism part 222c, a flow rate regulation part 222d, and a temperature regulation mechanism part 222e. The polishing fluid supply nozzle 222a supplies the polishing fluid to the polishing surface of the polishing pad 2200. The swing movement mechanism part 222c is supported by a support shaft 222b, and turnably moves the polishing fluid supply nozzle 222a with the support shaft 222b as as the turning center. The flow rate regulation part 222d regulates the flow rate of the polishing fluid. The temperature regulation mechanism part 222e regulates the temperature of the polishing fluid. The polishing fluid is a polishing liquid (slurry) or pure water, and may also include a chemical solution, and a dispersant may be added to the polishing liquid.

The dresser 223 includes a rotary movement mechanism part 223c, a vertical movement mechanism part 223d, and a swing movement mechanism part 223e. The rotary movement mechanism part 223c is supported by a dresser shaft 223a movable in the upper-lower direction, and rotatably drives the dresser 223 about the axis center thereof. The vertical movement mechanism 223d moves the dresser 223 in the upper-lower direction. The swing movement mechanism part 223e turnably moves the dresser 223 with the support shaft 223b as the turning center.

The atomizer 224 includes a swing movement mechanism part 224b and a flow rate regulation part 224c. The swing movement mechanism part 224b is supported by a support shaft 224a, and turnably moves the atomizer 224 with the support shaft 224a as as the turning center. The flow rate regulation part 224c regulates the flow rate of the cleaning fluid. The cleaning liquid is a mixed fluid of liquid (e.g., pure water) and gas (e.g., nitrogen gas) or liquid (e.g., pure water).

The wafer W is sucked and held on the lower surface of the top ring 221 and moved to predetermined positions PP1, PP2 on the polishing table 220, and then polished by being pressed by the top ring 221 against the polishing surface of the polishing pad 2200 to which the polishing fluid is supplied from the polishing fluid supply nozzle 222a.

### Finishing Part

The finishing part 23 includes multiple (three, in the embodiment) finishing units 23A to 23C respectively performing a finishing process on the wafer W and a wafer station 23D in which the wafers W after the polishing process can standby. The first to third finishing units 23A to 23C and the wafer station 23D are arranged and disposed along the longitudinal direction of the housing 20, and the first to third finishing units 23A to 23C respectively perform the finishing process in the arrangement order (finishing process order).

In the embodiment, the first finishing unit 23A performs a roll sponge cleaning process that cleans the wafer W after the polishing process by using a roll sponge 2300 as a finishing process of the most upstream process. The second finishing unit 23B performs a pen sponge cleaning process that cleans the wafer W after the roll sponge cleaning process by using a pen sponge 2301. The third finishing process 23C performs a drying process that dries the wafer W after the pen sponge cleaning process as a finishing process of the most downstream process. The wafer station 23D holds the wafer W after the polishing process that is delivered from a polishing process transporter (details of which will be described afterwards) 240, and performs a standby process that keeps the wafer W after the polishing process on standby until the wafer W is delivered to a finishing process transporter 241 (details of which will be described afterwards). The finishing process may for example, omit the roll sponge cleaning process and starts from the pen sponge cleaning process.

Also, in addition to or in place of any of the first and second finishing units 23A, 23B, the finishing part 23 may also include a finishing unit (not shown) performing a buff cleaning process that cleans the wafer W by using a buff, and any of the first and second finishing units 23A, 23B may be omitted. In addition, in the embodiment, it is described that the first to third finishing units 23A to 23C hold the wafer W in horizontal placement (hold horizontally), but the wafer W may also be held vertically or obliquely.

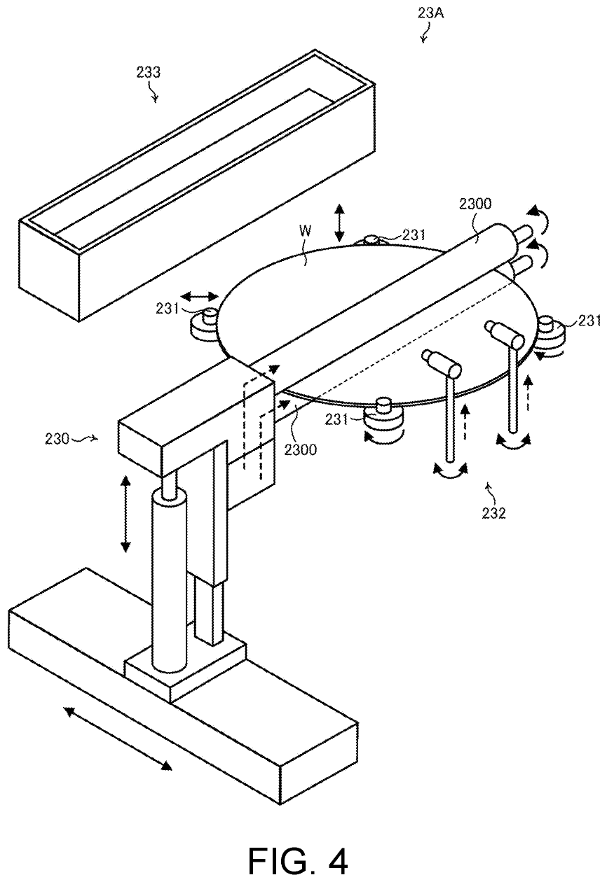

FIG. 4 is a perspective view illustrating an example of the first finishing unit 23A performing the roll sponge cleaning process. The first finishing unit 23A includes a substrate holding part 231, a cleaning fluid supply part 232, a substrate cleaning part 230, and a cleaning tool cleaning part 233. The substrate holding part 231 holds the wafer W. The cleaning fluid supply part 232 supplies a substrate cleaning fluid to the wafer W. The substrate cleaning part 230 rotatably supports the roll sponge 2300 and cleans the wafer W by bringing the roll sponge 2300 into contact with the wafer W. The cleaning tool cleaning part 233 cleans (self-cleans) the roll sponge 2300 by using a cleaning tool cleaning fluid. The substrate cleaning fluid may be any of pure wafer (rinse liquid) and a chemical solution, may be a fluid, may be a two-fluid in which liquid and gas are mixed, and may also include a solid such as dry ice. The cleaning tool cleaning fluid may be any of pure water (rinse liquid) and a chemical solution.

In the roll sponge cleaning process by using the first finishing unit 23A, the wafer W is rotated in the state of being held at a first finishing position PC1 by the substrate holding part 231. Then, in the state in which the substrate cleaning fluid is supplied to a cleaned surface of the wafer W from the cleaning fluid supply part 232, the wafer W is cleaned by brining the roll sponge 2300 rotated about the axis center by the substrate cleaning part 230 into sliding contact with the cleaned surface of the wafer W.

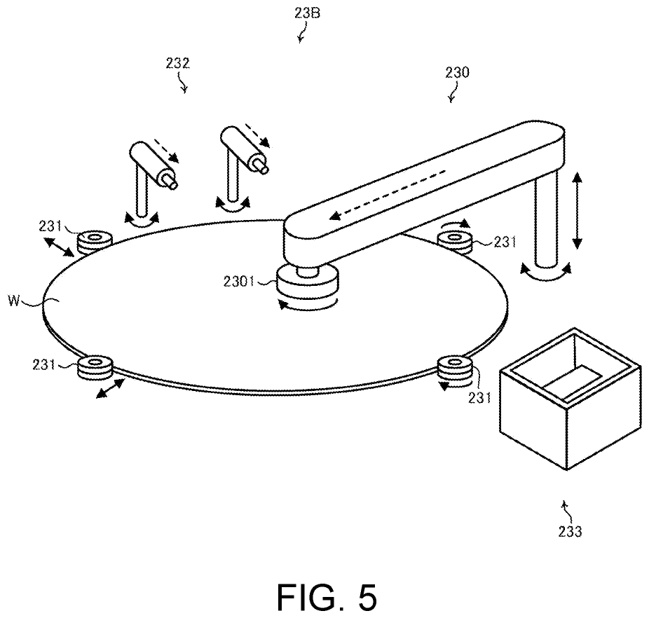

FIG. 5 is a perspective view illustrating an example of the second finishing unit 23B performing the pen sponge cleaning process. The second finishing unit 23B includes the substrate holding part 231, the cleaning fluid supply part 232, the substrate cleaning part 230, and the cleaning tool cleaning part 233. The substrate holding part 231 holds the wafer W. The cleaning fluid supply part 232 supplies a substrate cleaning fluid to the wafer W. The substrate cleaning part 230 rotatably supports the pen sponge 2301 and cleans the wafer W by bringing the pen sponge 2301 into contact with the wafer W. The cleaning tool cleaning part 233 cleans (self-cleans) the pen sponge 2301 by using a cleaning tool cleaning fluid.

In the pen sponge cleaning process by using the second finishing unit 23B, the wafer W is rotated in the state of being held at a second finishing position PC2 by the substrate holding part 231. Then, in the state in which the substrate cleaning fluid is supplied to the cleaned surface of the wafer W from the cleaning fluid supply part 232, the wafer W is cleaned by brining the pen sponge 2301 rotated about the axis center by the substrate cleaning part 230 into sliding contact with the cleaned surface of the wafer W.

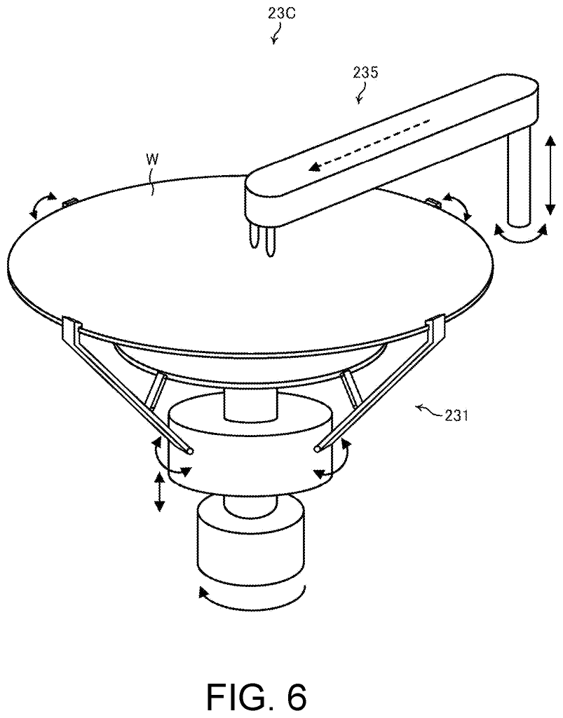

FIG. 6 is a perspective view illustrating an example of the third finishing unit 23C performing the drying process. The third finishing unit 23C includes the substrate holding part 231 holding the wafer W and a drying fluid supply part 235 supplying a substrate drying fluid to the wafer W. The substrate drying fluid, for example, is IPA steam and pure water (rinse liquid), and may also be a liquid, a two-fluid in which liquid and gas are mixed, and may also include a solid such as dry ice.

In the drying process by using the third finishing unit 23C, the wafer W is rotated in the state of being held at a third finishing position PC3 by the substrate holding part 231. Then, in the state in which the substrate drying fluid is supplied from the drying fluid supply part 235 to the cleaned surface of the wafer W, the drying fluid supply part 235 is moved to the side of a lateral edge part (radially outer side) of the wafer W. Then, the wafer W is dried by being rotated at a high speed.

### Substrate Transport Part

The substrate transport part 24 includes a polishing process transporter 240 and a finishing process transporter 241. As shown in FIG. 2, the polishing process transporter 240, as a transport unit, is movable along the direction in which the first and second polishing units 22A, 22B are arranged (the longitudinal direction of the housing 20), and is movable to the wafer station 23D as a second substrate delivery position PD2. The finishing process transporter 241, as a transport unit, is movable along the direction in which the wafer station 23D and the first to third finishing units 23A to 23C are arranged (the longitudinal direction of the housing 20).

The polishing process transporter 240 is configured to be able to access the first substrate delivery position PD1, first and second transport positions PT1, PT2, and the second substrate delivery position PD2. Therefore, as a transport process of the wafer W, the polishing process transporter 240 performs a pre-polishing transport process and a post-polishing transport process. In the pre-polishing transport process, the polishing process transporter 240 transports the wafer W from the first substrate delivery position PD1 to the first and second polishing units 22A, 22B (the first and second transport positions PT1, PT2, in the embodiment). In the post-polishing transport process, the polishing process transporter 240 transports the wafer W from the first and second polishing units 22A, 22B (the first and second transport positions PT1, PT2, in the embodiment) to the second substrate delivery position PD2.

The first substrate delivery position PD1 is a position of delivering the wafer W between the load/unload robot 211 and the polishing process transporter 240. The first substrate delivery position PD1 is a position set on the side of the load/unload robot 211 within the movement range of the polishing process transporter 240, and is accessed through moving of the load/unload robot 211.

The first and second transport positions PT1, PT2 are positions for respectively delivering the wafers W between the first and second polishing units 22A, 22B and the polishing process transporter 240. The first and second transport positions PT1, PT2 are disposed at a predetermined interval with the movement range of the polishing process transporter 240, and are accessed through swinging and moving of the top rings 221 of the first and second polishing units 22A, 22B.

The finishing process transporter 241 is configured to be able to access the second delivery position PD2 and the first to third finishing units 23A to 23C. Therefore, the finishing process transporter 241, as a transport process of the wafer W, performs a pre-finishing transport process and an in-finishing transport process. In the pre-finishing transport process, the finishing process transporter 241 transports the wafer W after the polishing process to the finishing unit 23A of the most upstream process from the second substrate delivery position PD2. In the in-finishing transport process, the finishing process transporter 241 transports the wafer W in the finishing process among the first to third finishing units 23A to 23C in the order of the finishing process. In the embodiment, the finishing process transporter 241, as the in-finishing transport processes, performs a first in-finishing transport process and a second in-finishing transport process. In the first in-finishing transport process, the finishing process transporter 241 transports the wafer W in the finishing process from the first finishing unit 23A to the second finishing unit 23B. In the second in-finishing transport process, the finishing process transporter 241 transports the wafer W in the finishing process from the second finishing unit 23B to the third finishing unit 23C.

The second substrate delivery position PD2 is a position of respectively delivering the wafer W between the polishing process transporter 240 and the finishing process transporter 241. The second substrate delivery position PD2 is a position set inside the wafer station 23D, and is accessed by respectively moving the polishing process transporter 240 and the finishing process transporter 241.

### Control Unit

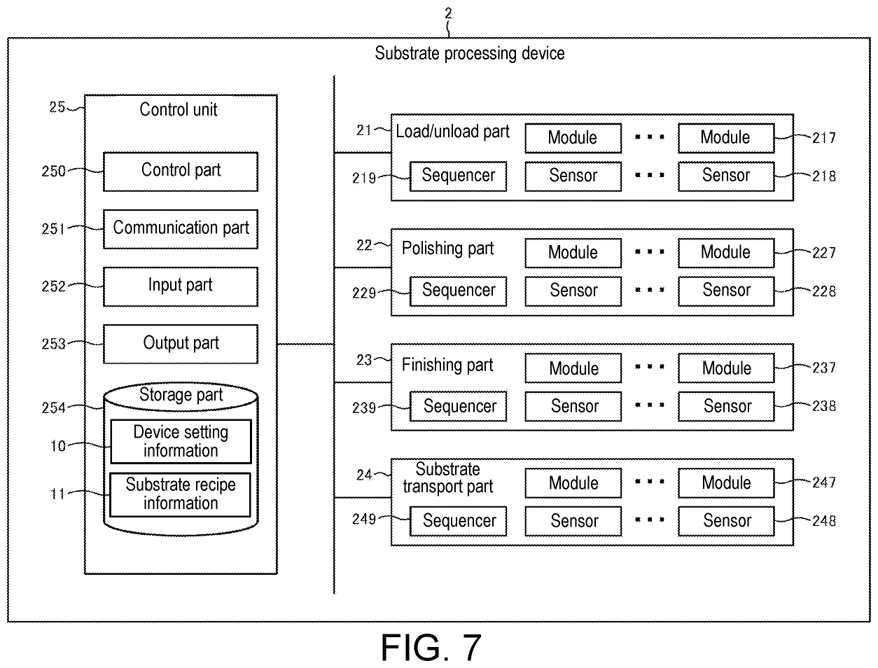

FIG. 7 is a block diagram illustrating an example of the substrate processing device 2. The control unit 25 is electrically connected with the respective parts 21 to 24, and functions as a control part that collectively controls the respective parts 21 to 24. In the following, although the control system (modules, sensors, sequencers) of the substrate transport part 24 is described as an example, the load/unload part 21, the polishing part 22, and the finishing part 23 also share basic configurations or functions. Therefore, descriptions in this regard will be omitted.

The substrate transport part 24 includes multiple modules 247, multiple sensors 248, and a sequencer 249. The modules 247 are respectively disposed at the respective transport units (e.g., the polishing process transporter 240, the finishing process transporter 241) and serve as control targets. The sensors 248 are respectively disposed in the modules 247 and detect data (detection values) required for controlling the respective modules 24. The sequencer 249 controls the operations of the respective modules 247 based on the detection values of the respective sensors 248. The modules 247 of the substrate transport part 24 include a rotary motor, a linear motor, an air actuator, a hydraulic actuator, etc., provided in the respective transport units. In addition, the sensors 248 of the substrate transport part 24 include, for example, an encoder sensor, a linear sensor, a limit sensor, and a contactless sensor detecting whether the wafer W is present.

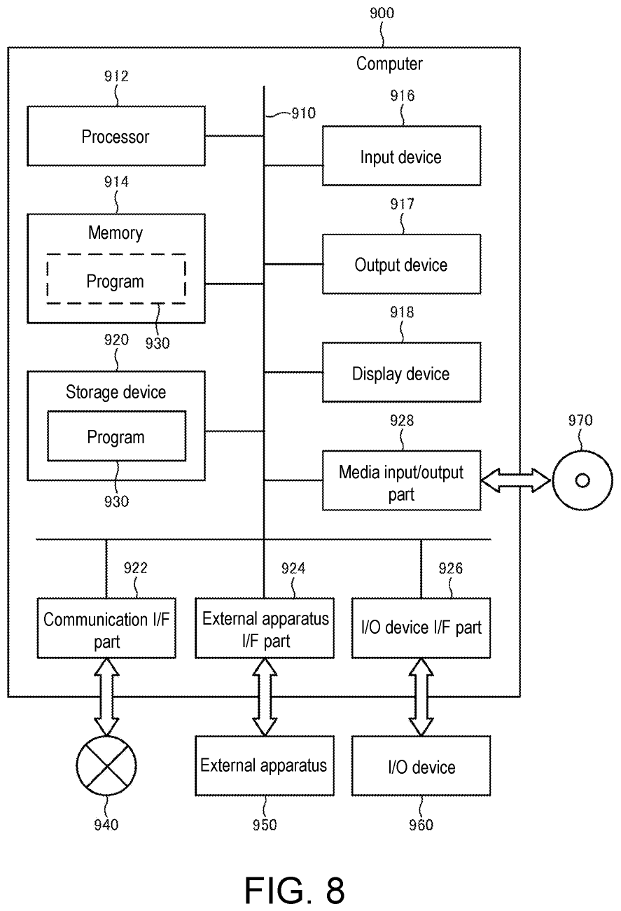

The control unit 25 includes a control part 250, a communication part 251, an input part 252, an output part 253, and a storage part 254. The control unit 25 is formed by, for example, a general-purpose or dedicated computer (see FIG. 8 to be described afterwards).

The communication part 251 is connected with the network 4, and functions as a communication interface for transmitting and receiving various data. The input part 252 receives various input operations, and the output part 253 functions as a user interface by outputting various information via a display screen, a signal tower lighting, a buzzer sound.

The storage part 254 stores various programs (operating system (OS), application program, web browser, etc.) and data (the device setting information 10, the substrate recipe information 11, etc.) used in the operation of the substrate processing device 2. The device setting information 10 and the substrate recipe information 11 are data editable by the user via a display screen.

The control part 250 acquires detection values of multiple sensors 218, 228, 238, 248 (referred to as “sensor group” in the following) via multiple sequencers 219, 229, 239, 249 (referred to as “sequencer group” in the following), and operates multiple modules 217, 227, 237, 247 (referred to as “module group” in the following) in cooperation. In addition, the substrate processing device 2 controls the respective parts 21 to 24 by using the control part 250, and executes automatic operation by performing the polishing process, the finishing process, the transport process, etc., in order on the wafers W in the wafer cassette.

### Hardware Configuration of Each Device

FIG. 8 is a view illustrating a hardware configuration of an example of a computer 900. Each of the control unit 25 of the substrate processing device 2 and the information processing device 3A is formed by a general-purpose or dedicated computer 900.

As shown in FIG. 8, the computer 900 mainly includes a bus 910, a processor 912, a memory 914, an input device 916, an output device 917, a display device 918, a storage device 920, a communication interface (I/F) part 922, an external apparatus I/F part 924, an input/output (I/O) device I/F part 926, and a media input/output part 928. The above components may be omitted as appropriate in accordance with the purpose of use of the computer 900.

The processor 912 is formed by one or more computational processing units (central processing unit (CPU), micro-processing unit (MPU), digital signal processor (DSP), graphic processing unit (GPU), neural processing unit (NPU), etc.,), and operates as a control part that controls the entire computer 900. The memory 914 stores various data and programs 930, and is formed by, for example, a volatile memory (DRAM, SRAM), a non-volatile memory (ROM), a flash memory, etc., that functions as a main memory.

The input device 916 is formed by, for example, a keyboard, a mouse, a numeric key pad, an electronic pen, etc., and functions as an input part. The output device 917 is formed by, for example, a sound (voice) output device, a vibration device, etc., and functions as an output part. The display 918 is formed by, for example, a liquid crystal display, an organic EL display, an electronic paper, a projector, etc., and functions as the output part. The input device 916 and the display device 918 may also be formed integrally, such as a touch panel display. The storage device 920 is formed by, for example, a HDD, SSD, etc., and functions as the storage part. The storage device 920 stores various data required for execution of the operating system and the programs 930.

The communication I/F part 922 is wiredly or wirelessly connected with a network 940 (may be the same as the network 4 of FIG. 1), such as the Internet or an intranet, and functions as a communication part performing data transmission/reception with another computer in accordance with a predetermined communication standard. The external apparatus I/F part 924 is wiredly or wirelessly connected with an external apparatus 950, such as a camera, a printer, a scanner, a reader/writer, and functions as a communication part performing data transmission/reception with the external apparatus 950 in accordance with a predetermined communication standard. The I/O device I/F part 926 is connected with I/O devices 960, such as various sensors, actuators, and functions as a communication part for transmitting/receiving various signals or data, such as a detection signal from a sensor or a control signal to an actuator, with the I/O devices 960. The media input/output part 928 is formed by, for example, a drive device, such as a DVD drive, a CD drive, a memory card slot, a USB connector, and reads/writes data from/to a medium (non-volatile memory storage medium) 970, such as a DVD, a CD, a memory card, a USB memory.

In the computer 900 having the configuration, the processor 912 calls the program 930 stored in the storage device 920 to the memory 914 and executes the program 930, and controls the respective parts of the computer 900 via the bus 910. The program 930 may also be stored in the memory 914, in place of the storage device 920. The program 930 may also be recorded in a medium 970 in a file format that can be installed or executed, and may be provided to the computer 900 via the media input/output part 928. The program 930 may also be provided to the computer 900 by downloading the program 930 from the network 940 via the communication I/F part 922. In addition, the computer 900 may also realize the various functions realized by executing the program 930 by the processor 912 by using hardware, such as a field-programmable gate array (FPGA), an application specific integrated circuit (ASIC).

The computer 900 may be formed by, for example, a desktop computer or a portable computer, and may be an electronic apparatus of any form. The computer 900 may be a client-type computer, and may also be a server-type computer or a cloud-type computer, such a so-called embedded computer like a control panel, a controller (including a microcontroller, a programmable logic controller, a sequencer), etc. The computer 900 may also be applied to a device other than the substrate processing device 2 and the information processing device 3A.

### Information Processing Device

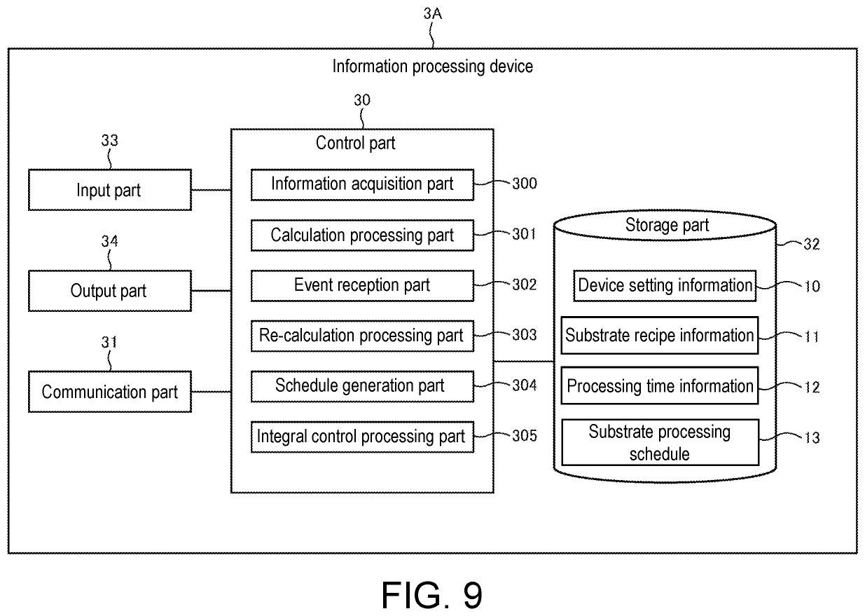

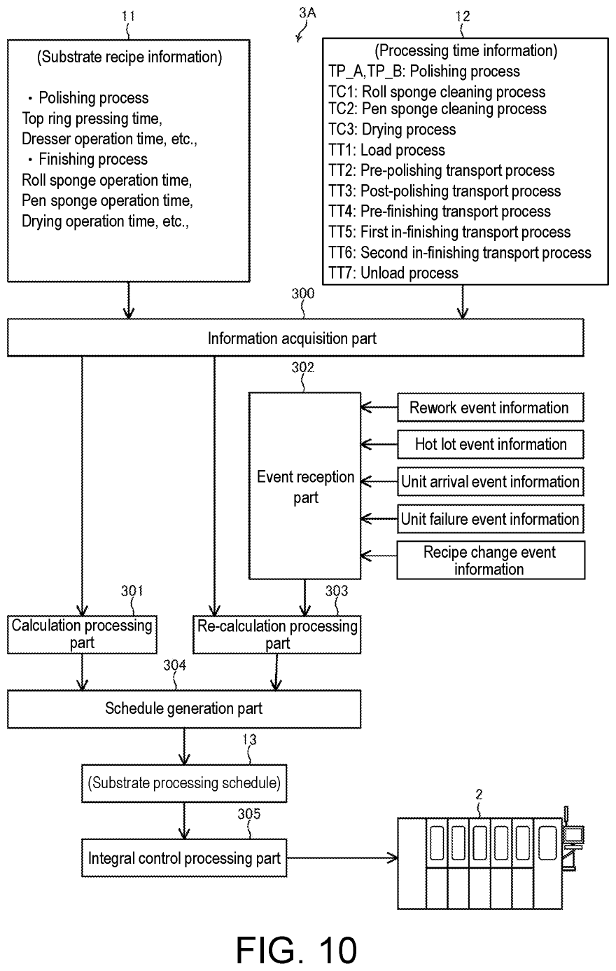

FIG. 9 is a block diagram illustrating an example of an information processing device 3A according to a first embodiment. FIG. 10 is a functional diagram illustrating an example of the information processing device 3A according to the first embodiment.

The information processing device 3A includes a control part 30, a communication part 31, a storage part 32, an input part 33, and an output part 34. Since the specific hardware configuration of the respective parts 30 to 34 shown in FIG. 9 is configured by the general-purpose or dedicated computer 900 shown in FIG. 8, detailed descriptions in this regard are omitted.

The control part 30 functions as an information acquisition part 300, a calculation processing part 301, an event reception part 302, a re-calculation part 303, a schedule generation part 304, and an integral control processing part 305. The communication part 31 is connected to an external device (e.g., the substrate processing device 2) via the network 4 and functions as a communication interface transmitting and receiving various data. The storage part 32 stores various programs (operating system, information processing program, etc.) and data (the device setting information 10, the substrate recipe information 11, the processing time information 12, the substrate processing schedule 13), etc., used in the operation of the information processing device 3A. The input part 33 receives various input operations, and the output part 34 outputs various information via a display screen or a sound, thereby functioning as a user interface.

The information acquisition part 300, for example, transmits/receives data to/from the substrate processing device 2 via the communication part 31, and acquires the substrate recipe information 11 and the processing time information 12 by referring to the storage part 32. The substrate recipe information 11 and the processing time information 12 may be acquired based on a user's input operation, and may also be acquired from an external production management device (not shown).

The substrate recipe information 11 is the information indicating processing contents of the polishing process and the finishing process. The processing contents of the polishing process include, for example, the table rotation speed by using the polishing table 220, the top ring pressing time by using the top ring 221, the wafer pressing load, the wafer rotation speed, the supply amount of the polishing liquid by using the polishing liquid supply part 222, the supply timing, the dresser operation time by using the dresser 223, the atomizer operation time by using the atomizer 224, etc. The processing contents of the finishing process include, for example, the roll sponge operation time, the roll sponge rotation speed, the wafer rotation speed, the supply amount of the substrate cleaning fluid, and the supply timing in the roll sponge cleaning process, the pen sponge operation time, the pen sponge rotation speed, the wafer rotation speed, the supply amount of the substrate cleaning fluid, the supply timing, the wafer rotation speed, the drying operation time in the drying process, and the wafer rotation speed in the pen sponge cleaning process, and the supply amount and the supply timing of the substrate drying fluid, etc. The substrate recipe information 11 may be set for each wafer W, and may also be set for every multiple wafers that form a lot.

The processing time information 12 is the information respectively indicating polishing time T required in the polishing process, finishing time TC required for performing the finishing process, and transport time TT required for the transport process. The information acquisition part 300 acquires, as polishing time TP, a polishing time TP_A required for the polishing process performed by the first polishing unit 22A and polishing time TP_B required for the polishing process performed by the second polishing unit 22B, for example, based on setting values related to the polishing time among the processing contents of the processing process indicated in the substrate recipe information 11. The information acquisition part 300 acquires, as finishing time TC, a finishing time TC1 required for the roll sponge cleaning process, a finishing time TC2 required for the pen sponge cleaning process, and a finishing time TC3 required for the drying process, for example, based on setting values related to the finishing time among the processing contents of the finishing process indicated by the substrate recipe information 11. The information acquisition part 300 acquires, as transport time TT, transport time TT1 to TT7 required for, for example, each of the load process, the pre-polishing transport process, the post-polishing transport process, the pre-finishing transport process, the in-finishing transport process (the first and second in-finishing transport processes, in the embodiment), and the unload process.

Regarding the processing time (the polishing time TP_A, TP_B, the finishing time TC1 to TC3, and the transport time TT1 to TT7), for example, the measurement values measuring the time when the polishing units 22A, 22B, the finishing units 23A to 23C, the transport units (e.g., the load/unload robot 211, the polishing process transporter 240, the finishing process transporter 241) actually operate may also be considered. At this time, for example, in the case where the measurement values are stored in the substrate processing device 2 or an external production management device, the information acquisition part 300 may acquire the measurement values, as the processing time, from the substrate processing device 2 or the external production management device, and may correct the processing time calculated from the substrate recipe information 11 based on the measurement values. In addition, the processing time may be a theoretical value calculated from the specification of each unit, and, in the case where the movement speed of each unit is included in the device setting information 10, the information acquisition part 300 may acquire the device setting information 10 from the substrate processing device 2 or the storage part 32 and calculate the processing time based on the device setting information 10. The processing time information 12 may be set for each wafer W, and may also be set for every multiple wafers that form a lot.

The calculation processing part 301 calculates the start timings of the respective processes when the respective processes are performed in order on a predetermined number of the wafers W in the substrate processing device 2. In the automatic operation of the substrate processing device 2, the respective processes are performed so that processes that can be performed simultaneously among the processes are performed in parallel, and processes that cannot be performed simultaneously among the processes are performed in serial, while maintaining the order of performing the respective processes. Therefore, based on the substrate recipe information 11 and the processing time information 12 acquired by the information acquisition part 300, the calculation processing part 301 calculates the start timings of the respective processes, so that the final processing end time at which the last wafer W after the finishing process is unloaded to the substrate unload position PE is the shortest. In place of or in addition to the final processing end time being the shortest, the calculation processing part 301 may also calculate the start timings of the respective processes, so that the post-polishing finishing start time from the end timing of the polishing process to the start timing of the finishing process of the most upstream process is uniform and minimum.

Various calculation processes may be used as the calculation process for the calculation processing part 301 to calculate the start timings of the respective processes.

For example, the calculation processing part 301 may also calculate the start timings of the respective processes by formulating an optimization issue and looking for an optimal solution, as described in Japanese Laid-open No. 2022-125311 of the Applicant. As a mathematical optimization method, for example, mixed integer linear programming (MIP) may be used, and as a method for looking for the optimal solution, any exploratory algorithm, such as exact solution, approximate solution, heuristic solution, etc., can be used.

In the mathematical optimization, for example, the processing order condition that determines the order of performing the respective processes and the simultaneous processing condition that determines processes that can or cannot be simultaneously performed among the respective processes are set as the constraint conditions for mathematical optimization, the final processing end time including the processing time required for the respective processes in the variables being the shortest is set as the objective function of the mathematical optimization, and the start timings of the respective processes are determined as the decision variable of the mathematic optimization, so as to carry out the mathematical optimization. In this way, the start timings of the respective processes are calculated. In the substrate processing device 2 according to the embodiment, the processing order condition is determined in the order of the load process (TT1), the pre-polishing transport process (TT2), the polishing process (TP), the post-polishing transport process (TT3), the standby process (WS), the pre-finishing transport process (TT4), the roll sponge cleaning process (TC1), the first in-finishing transport process (TT5), the pen sponge cleaning process (TC2), the second in-finishing transport process (TT7), the drying process (TC3), and the unload process (TT7). Meanwhile, as the simultaneous processing condition, the polishing process (TP_A) performed by the first polishing unit 22A and the polishing process (TP_B) performed by the second polishing unit 22B are determined as processes that can be performed simultaneously, and the pre-finishing transport process (TT4), the first in-finishing transport process (TT5), and the second in-finishing transport process (TT6) are determined as processes that cannot be performed simultaneously.

In addition, as described in Japanese Laid-open No. 2022-130013, the calculation processing part 301 may also generate a time table determining the start timings of the respective processes for each processing pattern in which the order of loading the wafer W into the substrate processing device 2 is changed, and select the processing pattern with the shortest final processing end time among the patterns, thereby calculating the start timings of the respective processes.

The event reception part 302 receives event information indicating an occurrence situation of an event that affects the execution of any of the respective processes. The event information include, for example, information relating to rework, hot lot, unit arrival, unit failure, and recipe change. However, the event information is not limited to these types of information, as long as it affects the execution of any of the processes.

Event information related to rework (referred to as “rework event information” in the following) indicates that the polishing process is performed again on the wafer W on which the polishing process has been performed, or the finishing process is performed again on the wafer W on which the finishing process has been performed. The rework event information includes, for example, the wafer ID for identifying an interrupt wafer (interrupt substrate) serving as the rework target, the processing contents (may also be the substrate recipe information 11) for the interrupt wafer W, etc. The rework event information, for example, is generated based on an inspection result (e.g., film thickness, etc.) of an inspection device (not shown) disposed inside or outside the substrate processing device 2 and received from the the inspection device.

Event information related to hot lot (referred to as “hot lot event information” in the following) indicates that the respective processes are performed on an interrupt wafer (interrupt substrate) not included in the wafers W when the start timings of the respective processes are calculated by the calculation processing part 301. The hot lot event information includes, for example, the wafer ID for identifying the interrupt wafer as the hot lot target, the processing contents (may also be the substrate recipe information 11) for the interrupt wafer, etc. The hot lot event information, for example, is received from the external production management device (not shown).

Event information related to unit arrival (referred to as “unit arrival event information” in the following) indicates that the wafer W has arrived at the polishing units 22A, 22B when the transport process transporting the wafer W is performed with respect to the polishing units 22A, 22B, or the wafer W has arrived at the finishing units 23A to 23C when the transport process transporting the wafer W is performed with respect to the finishing units 23A to 23C. The unit arrival event information, for example, includes the wafer ID for identifying the wafer W as the target, the unit ID for identifying the unit (the polishing units 22A, 22B, the finishing units 23A, 23C) which the wafer W has arrived at, the arrival time when the wafer W arrives at the unit, etc. The unit arrival event information is generated based on the detection results of the sensors 218, 228, 238, 248 included in the substrate processing device 2, for example, and received from the substrate processing device 2.

Event information related to unit failure (referred to as “unit failure event information” in the following) indicates that a failure (including a sign of failure) occurs in the polishing units 22A, 22B, the finishing units 23A to 23C, or the transport units (e.g., the load/unload robot 211, the polishing process transporter 240, the finishing process transporter 241). The unit failure event information includes, for example, the unit ID for identifying the unit (the polishing units 22A, 22B, the finishing units 23A to 23C, the transport unit) as the target, the failure occurrence time when the failure occurs, and the failure contents indicating the contents of the failure, etc. The unit failure event information is generated based on the detection results of the sensors 218, 228, 238, 248 included in the substrate processing device 2, for example, and received from the substrate processing device 2. Also, in the case where the cause of the failure is removed through maintenance, etc., and the failure is repaired, the unit failure event information indicating that the failure has been repaired is received.

Event information related to recipe change (referred to as “recipe change event information” in the following) indicates that the substrate recipe information 11 determining the processing contents of the polishing process is changed or the substrate recipe information 11 determining the processing contents of the finishing process is changed. The recipe change event information includes, for example, the wafer ID for identifying the wafer W as the target, the processing contents after the change to the wafer W (may also be the substrate recipe information 11 after the change), etc. The recipe change event information, for example, is received from the substrate processing device 2, an external production management device (not shown), a user terminal device (not shown).

When the event reception part 302 receives the event information during the execution of the respective processes by the substrate processing device 2 in accordance with the start timings of the respective processes calculated by the calculation processing part 301, the re-calculation processing part 303 re-calculates the start timings of the respective processes based on the occurrence situation of the event indicated in the event information. A calculation process same as or different from that of the calculation processing part 301 may be used as the calculation process performed by the re-calculation processing part 303 to re-calculate the start timings of the respective processes. At this time, it suffices as long as the re-calculation processing part 303 refers to information required for calculating the difference in the substrate recipe information 11 and the processing time information 12 acquired by the information acquisition part 300.

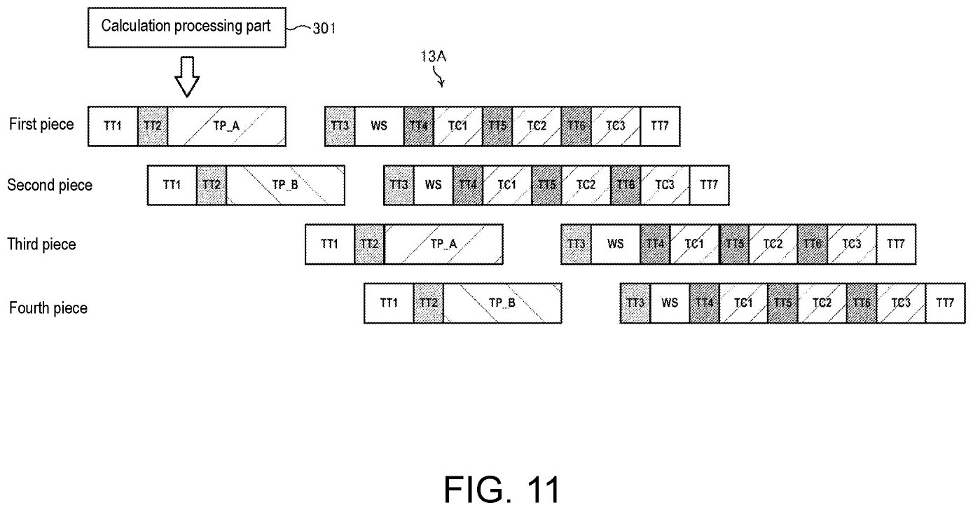

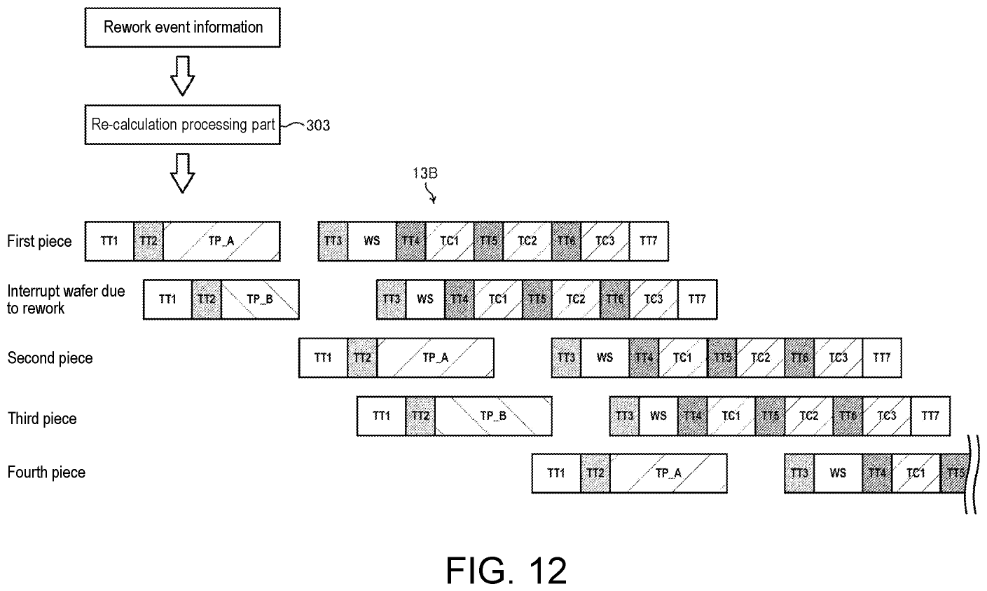

The schedule generation part 304 generates an initial substrate processing schedule 13 (see FIG. 11 to be described afterwards) determined by using the start timings of the respective processes calculated by the calculation processing part 301. In addition, the schedule generation part 304 generates an updated substrate processing schedule 13 (see FIGS. 12 to 17 to be described afterwards) determined by using the start timings of the respective processes re-calculated by the re-calculation processing part 303. The schedule generation part 304 may also evaluate the substrate processing schedule 13, and calculate, as the evaluation result, an evaluation index of the substrate processing schedule 13. Examples of the evaluation index of the substrate processing schedule 13 include, for example, the processed number (WPH) of wafers W per unit time, the tact time of the respective processes, the rate-limiting processing requiring the longest processing time among the respective processes, the variation degree of the post-polishing finishing start time, etc.

FIG. 11 is a diagram illustrating an example of an initial substrate processing schedule 13A. The initial substrate processing schedule 13A shown in FIG. 11 is determined by using the start timings of the respective processes calculated by the calculation processing part 301 before the substrate processing device 2 executes the respective processes. Although FIG. 11 illustrates the start timings of the respective processes for four wafers W, the start timings of the respective processes may be determined similarly for the fifth and subsequent wafers W.

FIG. 12 is a diagram illustrating an example of a substrate processing schedule 13B generated when the rework event information is received. The substrate processing schedule 13B shown in FIG. 12 is determined by using the start timings of the respective processes re-calculated by the re-calculation processing part 303 when the rework event information is received. In FIG. 12, the following case is shown: the rework event information indicates that the polishing process and the finishing process are performed again on the wafer W as the rework target, and the start timings of the respective processes are recalculated, so that the polishing process and the finishing process are performed on the interrupt wafer as the rework target between the first wafer W and the second wafer W. At this time, the case where the polishing time TP of the polishing process for the interrupt wafer as the rework target is set to be shorter than other wafers W is shown.

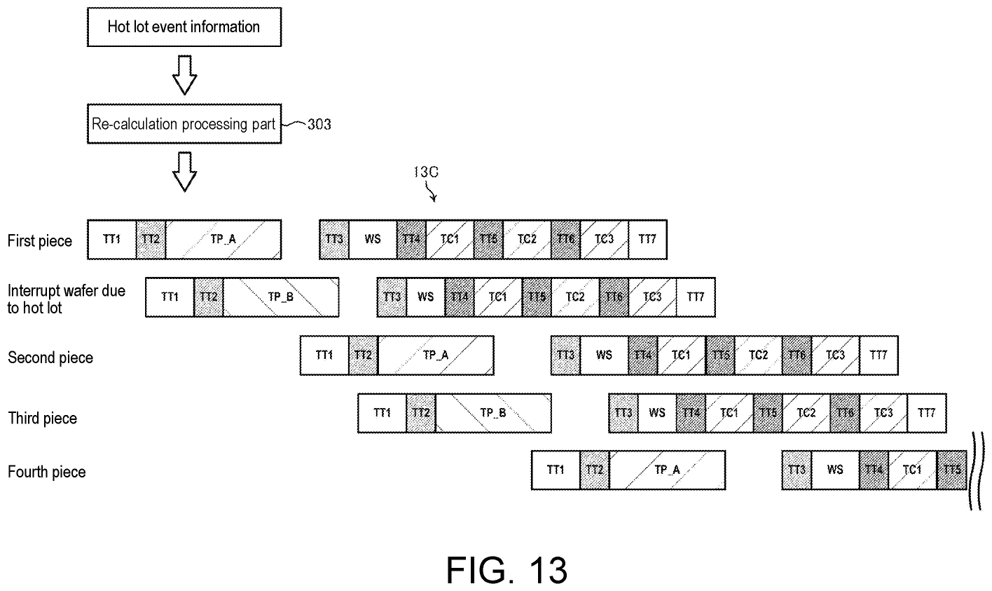

FIG. 13 is a diagram illustrating an example of a substrate processing schedule 13C generated by the re-calculation processing part 303 when the hot lot event information is received. The substrate processing schedule 13C shown in FIG. 13 is determined by using the start timings of the respective processes re-calculated by the re-calculation processing part 303 when the hot lot event information is received. In FIG. 13, the following case is shown: the start timings of the respective processes are recalculated, so that the polishing process and the finishing process are performed on the interrupt wafer as the hot lot target between the first wafer W and the second wafer W.

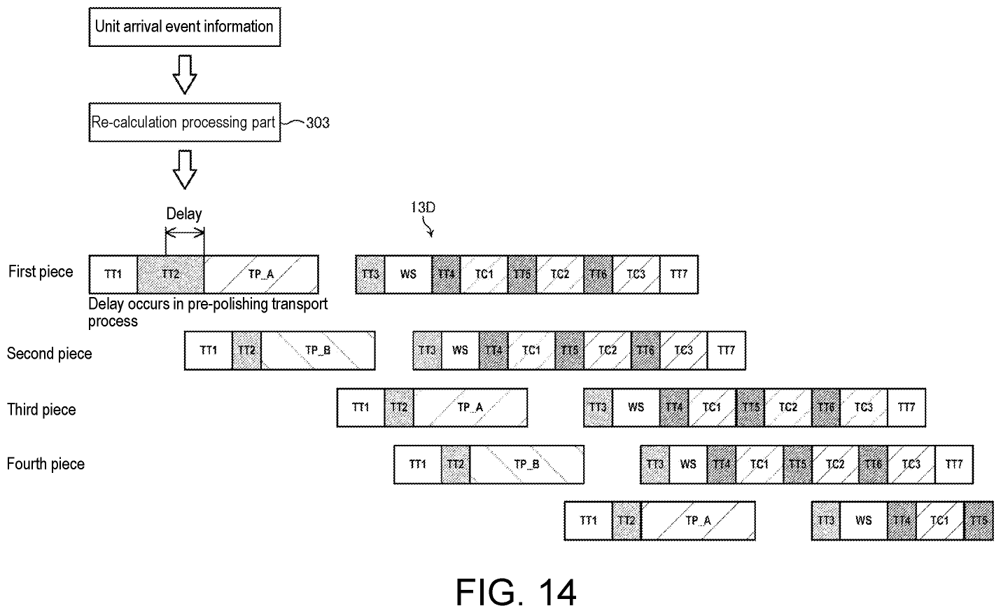

FIG. 14 is a diagram illustrating an example of a substrate processing schedule 13D generated by the re-calculation processing part 303 when the unit arrival event information is received. The substrate processing schedule 13D shown in FIG. 14 is determined by using the start timings of the respective processes re-calculated by the re-calculation processing part 303 when the unit arrival event information is received. FIG. 14 illustrates the case where the unit arrival event information indicates that the arrival time at which the first wafer W arrives at the first polishing unit 22A is delayed when the transport process transporting the first wafer W to the first polishing unit 22A is performed.

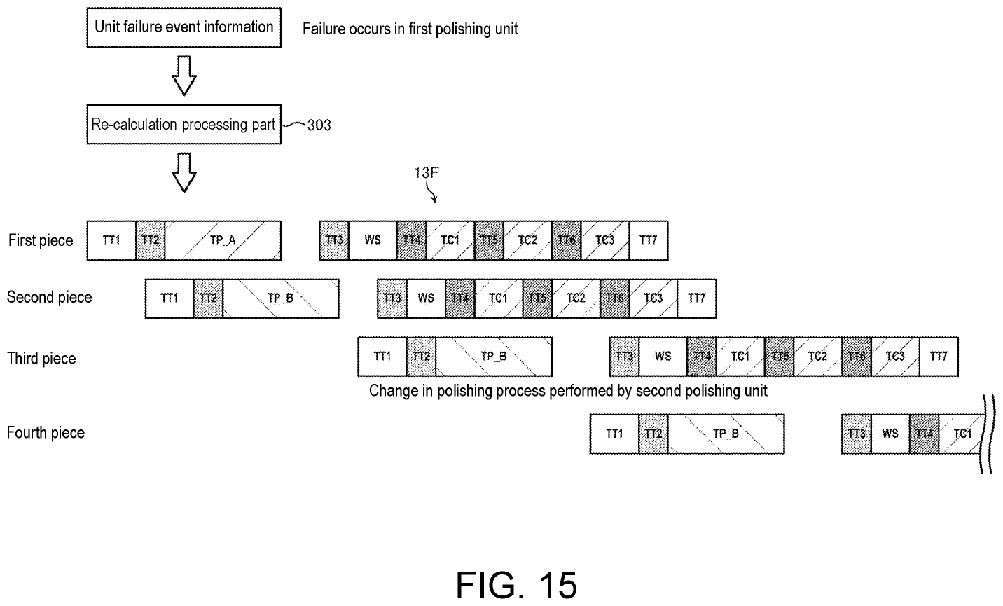

FIG. 15 is a diagram illustrating an example of a substrate processing schedule 13E generated by the re-calculation processing part 303 when the unit failure event information is received. The substrate processing schedule 13E shown in FIG. 15 is determined by using the start timings of the respective processes re-calculated by the re-calculation processing part 303 when the unit failure event information is received. FIG. 15 illustrates the following case: the unit failure event information indicates that a failure occurs in the first polishing unit 22A after the polishing process on the first wafer W ends, and the start timings of the respective processes are re-calculated, so that the polishing process on the second and subsequent wafers W is performed by the polishing unit 22B.

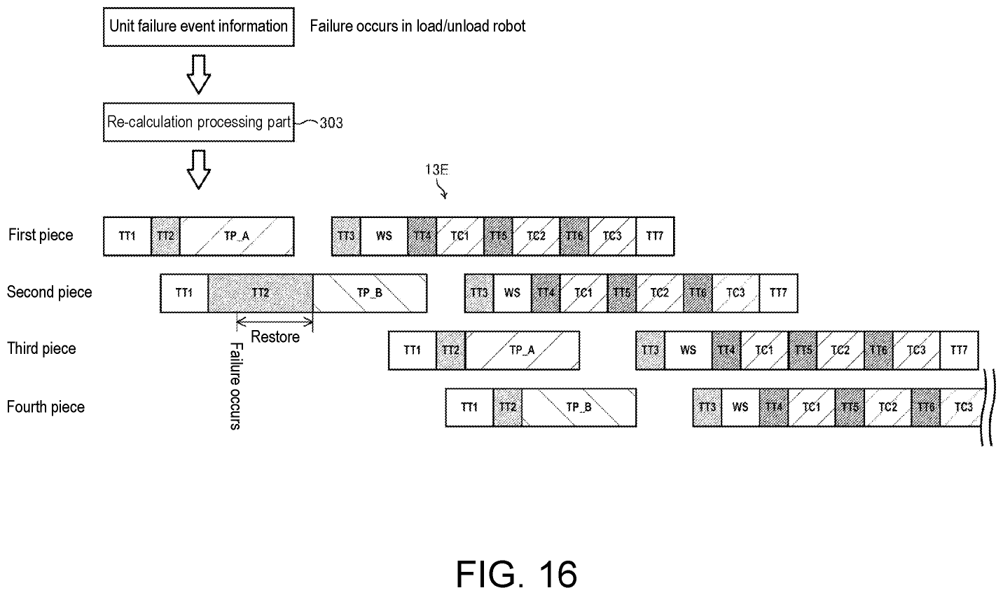

FIG. 16 is a diagram illustrating an example of a substrate processing schedule 13F generated by the re-calculation processing part 303 when the unit failure event information is received. The substrate processing schedule 13F shown in FIG. 16 is determined by using the start timings of the respective processes re-calculated by the re-calculation processing part 303 when the unit failure event information is received. FIG. 16 illustrates the following case: the unit failure event information indicates that a failure occurs in the load/unload robot 211 during the transport process transporting the second wafer W to the second polishing unit 22B, the failure of the load/unload robot 211 is repaired, and the start timings of the respective processes are re-calculated, so as to resume the respective processes on the second and subsequent wafers W.

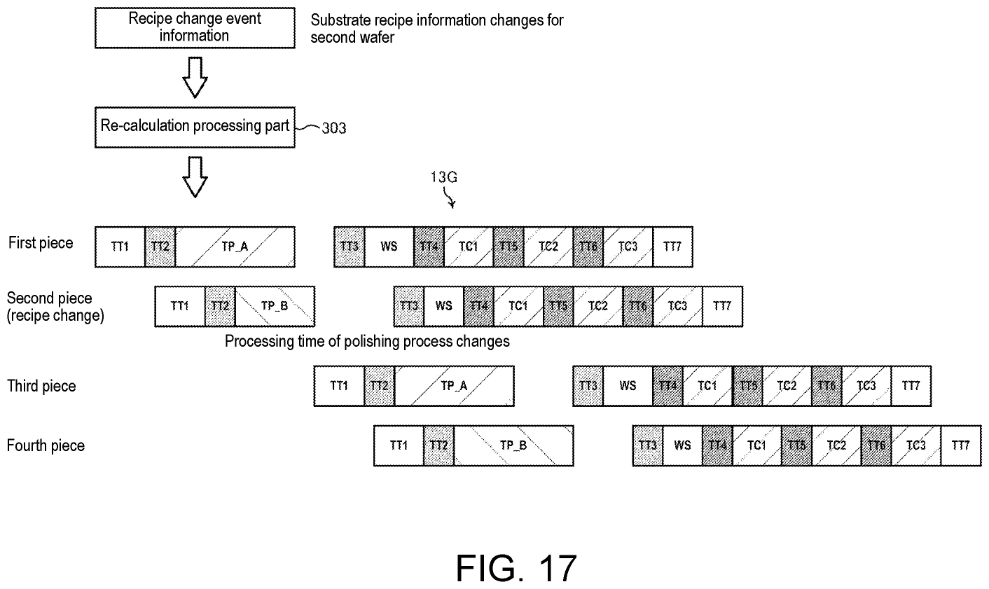

FIG. 17 is a diagram illustrating an example of a substrate processing schedule 13G generated by the re-calculation processing part 303 when the recipe change event information is received. The substrate processing schedule 13G shown in FIG. 17 is determined by using the start timings of the respective processes re-calculated by the re-calculation processing part 303 when the recipe change event information is received. FIG. 17 illustrates the following cases: the recipe change event information indicates that the processing contents of the polishing process in the substrate recipe information 11 on the second wafer W are changed, and the start timings of the respective processes are re-calculated, so that the polishing process on the second wafer W is executed by using the processing contents after the change.

The integral control processing part 305 controls the respective processing units by instructing the start timings of the respective processes based on the substrate processing schedule 13 (13A to 13G) generated by the schedule generation part 304. In the embodiment, the respective processing units include the polishing units 22A, 22B, the finishing units 23A to 23C, and the transport units (e.g., the load/unload robot 211, the polishing processing transporter 240, the finishing process transporter 241).

### Information Processing Method

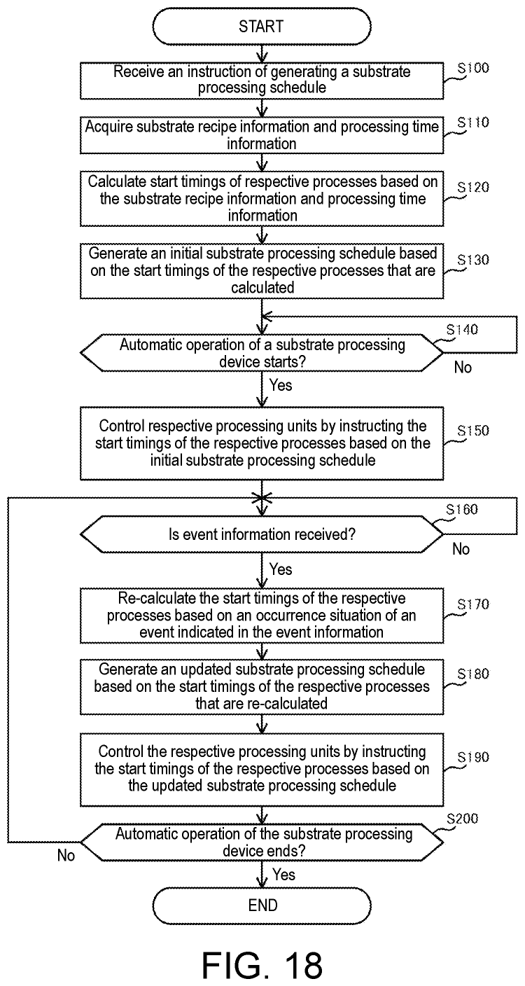

FIG. 18 is a flowchart illustrating an example of an information processing method performed by the information processing device 3A according to the first embodiment.

Firstly, in Step S100, the user, for example, designates the generation condition (the lot number or the processing number, etc., of the wafers W as the target of automatic operation) in the information processing device 3A, and inputs a generation instruction of the substrate processing schedule 13. Accordingly, the information processing device 3A receives the generation instruction.

Then, in Step S110, the information acquisition part 300 acquires the substrate recipe information 11 and the processing time information 12 based on the input operation received in Step S100. For example, in the case where the lot number is instructed, the substrate recipe information 11 associated with the lot number is acquired, and the processing time information 12 is acquired based on the substrate recipe information 11.

Then, in Step S120, based on the substrate recipe information 11 and the processing time information 12 acquired in Step S120, the calculation processing part 301 calculates the start timings of the respective processes, so that the final processing end time at which the last wafer W after the finishing process is unloaded to the substrate unload position PE is the shortest.

Then, in Step S130, the schedule generation part 304 generates the initial substrate processing schedule 13 (e.g., the initial substrate processing schedule 13A shown in FIG. 11) determined by using the start timings of the respective processes calculated in Step S120.

Then, in the case where the automatic operation of the substrate processing device 2 is started (Step S140: Yes), in Step S150, the integral control processing part 305 controls the respective processing units (the polishing units 22A, 22B, the finishing units 23A to 23C, and the transport units) by instructing the start timings of the respective processes based on the substrate processing schedule 13 generated in Step S130.

Then, in S160, during the execution of the automatic operation, the event reception part 302 monitors whether an event that affects the execution of any of the respective processes occurs. That is, the event reception part 302 monitors whether event information is received during the execution of the respective processes by the substrate processing device 2 in accordance with the start timings of the respective processes calculated in Step S120.

Then, when the event reception part 302 receives the event information (S160: Yes) during the automatic operation of the substrate processing device 2, in S170 (re-calculation processing process), the re-calculation processing part 303 re-calculates the start timings of the respective processes based on the occurrence situation of the event indicated in the event information.

Then, in Step S180, the schedule generation part 304 generates the updated substrate processing schedule 13 (e.g., the updated substrate processing schedules 13B to 13G shown in FIGS. 12 to 17) determined by using the start timings of the respective processes re-calculated by in Step S170.

Then, in Step S190, the integral control processing part 305 controls the respective processing units by instructing the start timings of the respective processes based on the updated substrate processing schedule 13 generated in Step S180.

Then, in the case where the automatic operation of the substrate processing device 2 does not end, but continues, the flow returns to Step S160. By repetitively executing Steps S170 to S190 every time when the event information is received in Step S160, a series of information processing methods shown in FIG. 18 are executed. In the information processing method, Step S110 is equivalent to the information acquisition process, Step S120 is equivalent to the calculation processing process, Step S130, Step S180 are equivalent to the schedule generation process, Step S160 is equivalent to the event reception process, Step S170 is equivalent to the re-calculation processing process, Steps S150, S190 are equivalent to the integral control processing process.

Based on the above, according to the information processing device 3A and the information processing method according to the embodiment, when the event information is received during the execution of the respective processes by the substrate processing device 2 in accordance with the start timings of the respective processes calculated by the calculation processing part 301, the re-calculation processing part 303 re-calculates the start timings of the respective processes based on the occurrence situation of the event indicated in the event information. Therefore, the processing efficiency of the substrate processing device 2 can be suppressed from deteriorating even in the case where various events occur during automatic operation. At this time, the integral control processing part 305 can operate the respective units in accordance with the re-calculated start timings of the respective processes through integrally controlling the substrate processing device 2.

### Second Embodiment

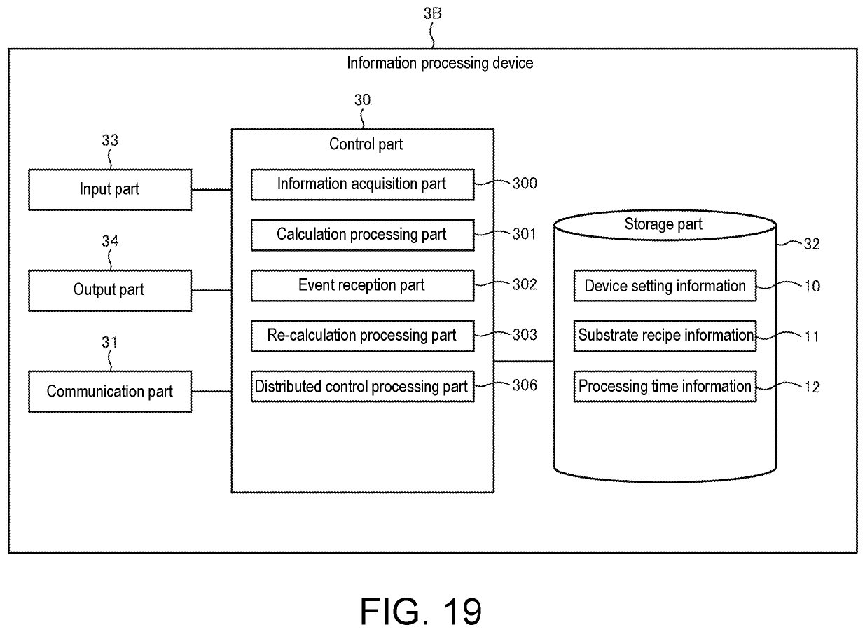

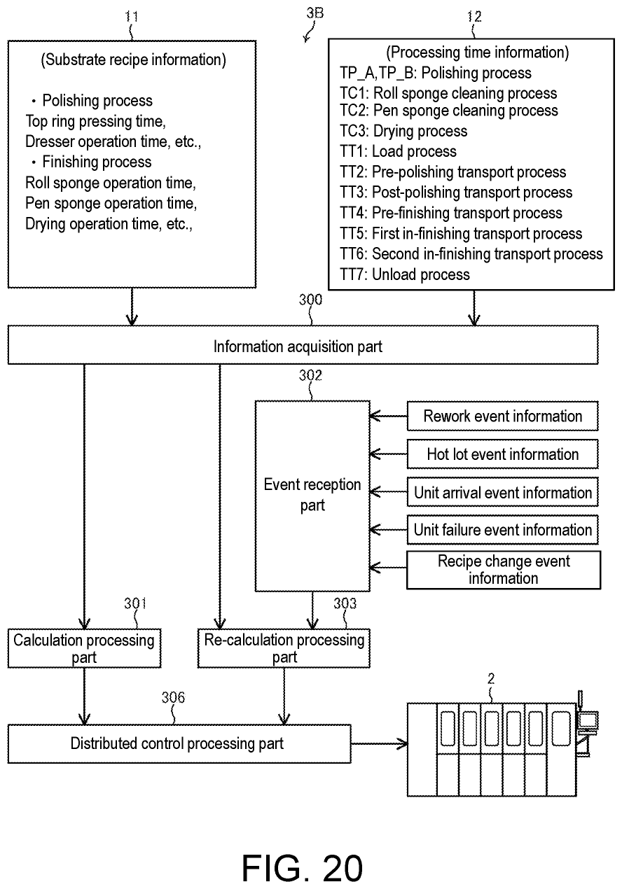

FIG. 19 is a block diagram illustrating an example of an information processing device 3B according to a second embodiment. FIG. 20 is a functional diagram illustrating an example of the information processing device 3B according to the second embodiment.

The information processing device 3B according to the second embodiment differs from the information processing device 3A according to the first embodiment in that, in place of the schedule generation part 304 and the integral control processing part 305, the information processing device 3B according to the second embodiment includes a distributed control processing part 306. Since the rest of the configuration is the same as that of the first embodiment, the same reference symbols are used, and detailed descriptions are omitted.

The control part 30 functions as the information acquisition part 300, the calculation processing part 301, the event reception part 302, the re-calculation part 303, and the distributed control processing part 306.

The distributed control processing part 306 controls the polishing units 22A, 22B by instructing the polishing units 22A, 22B the start timings of the polishing process calculated or re-calculated by the calculation processing part 301 or the re-calculation processing part 303 in accordance with the timings at which the wafer W arrives at the polishing units 22A, 22B when the transport process transporting the wafer W to the polishing units 22A, 22B is performed.

In addition, the distributed control processing part 306 controls the finishing units 23A to 23C by instructing the finishing units 23A to 23C the start timings of the finishing process calculated or re-calculated by the calculation processing part 301 or the re-calculation processing part 303 in accordance with the timings at which the wafer W arrives at the finishing units 23A to 23C when the transport process transporting the wafer W to the finishing units 23A to 23C is performed.

### Information Processing Method

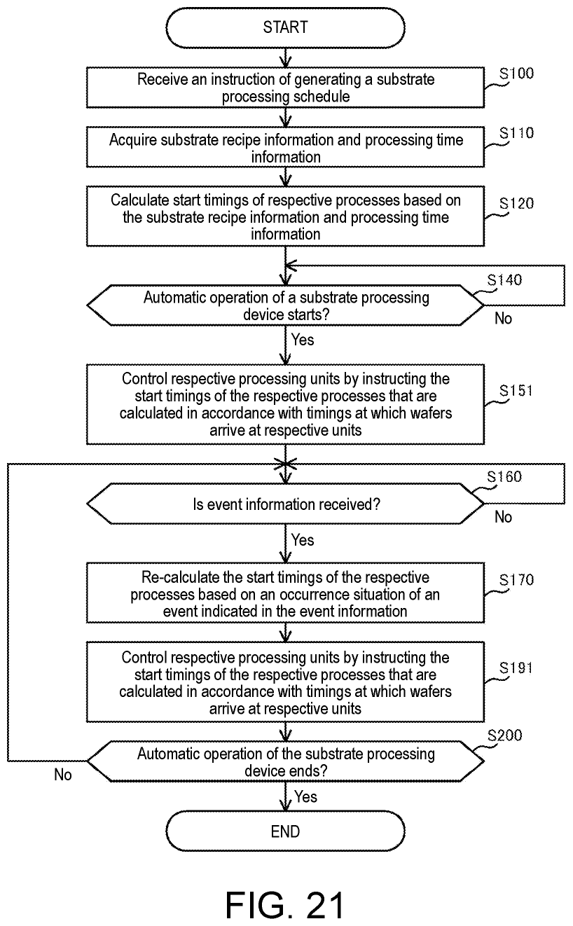

FIG. 21 is a flowchart illustrating an example of an information processing method performed by the information processing device 3B according to the second embodiment.

The information processing method performed by the information processing device 3B according to the second embodiment differs from the information processing method (the flowchart shown in FIG. 18) according to the first embodiment in the point that a distributed control processing process is performed. In Steps S151, S191, the distributed control process part 306 controls the respective processing units (the polishing units 22A, 22B, the finishing units 23A to 23C, and the transport units) by instructing the respective processing units the start timings of the respective processes calculated or re-calculated by the calculation processing part 301 or the re-calculation processing part 303. Since the rest of the steps are the same as those of the first embodiment, the same reference symbols are used, and detailed descriptions are omitted.

Based on the above, according to the information processing device 3B and the information processing method according to the embodiment, when the event information is received during the execution of the respective processes by the substrate processing device 2 in accordance with the start timings of the respective processes calculated by the calculation processing part 301, the re-calculation processing part 303 re-calculates the start timings of the respective processes based on the occurrence situation of the event indicated in the event information. Therefore, the processing efficiency of the substrate processing device 2 can be suppressed from deteriorating even in the case where various events occur during automatic operation. At this time, the distributed control processing part 306 can operate the respective units in accordance with the re-calculated start timings of the respective processes through controlling the substrate processing device 2 in a distributed manner.

### Other Embodiments

The invention is not limited to the embodiments described above, and can be implemented with various modifications without departing from the spirit of the invention. All of modifications still fall within the technical idea of the invention.

In the embodiments, the substrate processing device 2 and the information processing devices 3A, 3B are described as being configured as different devices. However, the substrate processing device 2 and the information processing devices 3A, 3B may also be formed by a single device. For example, the information processing devices 3A, 3B may also be incorporated into the control unit 25 of the substrate processing device 2. In addition, a portion of the functions provided in the information processing devices 3A, 3B may also be realized by the control unit 25 of the substrate processing device 2. For example, the control unit 25 of the substrate processing device 2 may also function as the calculation processing part 301, the event reception part 302, the re-calculation processing part 303, and the schedule generation part 304, and may also function as the integral control processing part 305 or the distributed control processing part 306.

In the embodiments, the substrate processing device 2 is described as performing a chemical mechanical polishing process as a polishing process. However, in place of the chemical mechanical polishing process, the substrate processing device 2 may also perform a physical mechanical polishing process.

In the embodiments, as shown in FIG. 2, the case where the substrate processing device 2 includes the respective processing units (the polishing units, the finishing units, the transport units) is described. However, as the configurations of the respective units, the quantities, arrangement, upstream-downstream relationship, parallel relationship, serial relationship, etc., of the respective processes are not limited to the example of FIG. 2, and may also be modified as appropriate. For example, the quantity of the polishing units may also be three or more, the transport processes may also be configured to be performed in parallel by providing, as the transport units, multiple polishing process transporters 240 or multiple finishing process transporters 241, and the finishing process may be configured to be performed in parallel by setting the first to third finishing units 23A to 23C as one set and providing multiple sets of the first to third finishing units 23A to 23C as the processing units. In addition, the delivery positions of the wafer W between the respective units and the temporary standby positions of the wafer W may be changed as appropriate, and the quantity thereof may be added as appropriate. In the above case, the calculation process at the time of calculating the start timings of the respective processes in the calculation processing part 301 and the re-calculation processing part 303 may be changed in accordance with the configurations of the respective processing units.

### Information Processing Program

The invention can also provide in the form of a program (information processing program) causing the computer 900 to function as the respective parts provided in the information processing devices 3A, 3B or a program (information processing program) causing the computer 900 to execute the respective processes provided in the information processing method according to the embodiments.

What is claimed is:

1. An information processing device, comprising:
a calculation processing part, calculating start timings of respective processes when the respective processes are performed in order on a predetermined number of substrates in a substrate processing device, the substrate processing device comprising: a plurality of polishing units performing a polishing process on the substrates in parallel; a plurality of finishing units, performing a finishing process on the substrates after the polishing process in a finishing processing order; and a plurality of transport units, performing a transport process for transporting the substrates;
an event reception part, receiving event information indicating an occurrence situation of an event affecting execution of any of the respective processes; and
a re-calculation part, re-calculating the start timings of the respective processes based on the occurrence situation of the event indicated in the event information when the event information is received by the event reception part during execution of the respective processes by the substrate processing device in accordance with the start timings of the respective processes calculated by the calculation processing part.

2. The information processing device as claimed in claim 1, wherein the event information is information related to rework, which indicates that the polishing process is performed again on the substrate on which the polishing process has been performed, or that the finishing process is performed again on the substrate on which the finishing process has been performed.

3. The information processing device as claimed in claim 1, wherein the event information is information related to hot lot, which indicates that the respective processes are performed on an interrupt substrate not included in the substrates when the start timings of the respective processes are calculated by the calculation processing part.

4. The information processing device as claimed in claim 1, wherein the event information is information related to unit arrival, which indicates that the substrate has arrived at the polishing unit when the transport process transporting the substrate is performed with respect to the polishing unit, or that the substrate has arrived at the finishing unit when the transport process transporting the substrate is performed with respect to the finishing unit.

5. The information processing device as claimed in claim 1, wherein the event information is information related to a unit failure, which indicates that a failure occurs in the polishing unit, the finishing unit, or the transport unit.

6. The information processing device as claimed in claim 1, wherein the event information is information related to recipe change, which indicates that recipe information determining processing contents of the polishing process is changed or that recipe information determining processing contents of the finishing process is changed.

7. The information processing device as claimed in claim 1, comprising:
a schedule generation part, generating a substrate processing schedule determined by using the start timings of the respective processes calculated or re-calculated by the calculation processing part or the re-calculation processing part; and
an integral control processing part, controlling the polishing units, the finishing units, and the transport units by instructing the start timings of the respective processes based on the substrate processing schedule generated by the schedule generation part.

8. The information processing device as claimed in claim 1, comprising:
a distributed control processing part, controlling the polishing unit by instructing the polishing unit a start timing of the polishing process calculated or re-calculated by the calculation processing part or the re-calculation processing part in accordance with a timing at which the substrate arrives at the polishing unit when the transport process transporting the substrate is performed with respect to the polishing unit, and controlling the finishing unit by instructing the finishing unit a start timing of the finishing process calculated or re-calculated by the calculation processing part or the re-calculation processing part in accordance with a timing at which the substrate arrives at the finishing unit when the transport process transporting the substrate is performed with respect to the finishing unit.

9. An information processing method, comprising:
a calculation processing process, calculating start timings of respective processes when the respective processes are performed in order on a predetermined number of substrates in a substrate processing device, the substrate processing device comprising: a plurality of polishing units performing a polishing process on the substrates in parallel; a plurality of finishing units, performing a finishing process on the substrates after the polishing process in a finishing processing order; and a plurality of transport units, performing a transport process for transporting the substrates;
an event reception process, receiving event information indicating an occurrence situation of an event affecting execution of any of the respective processes; and
a re-calculation process, re-calculating the start timings of the respective processes based on the occurrence situation of the event indicated in the event information when the event information is received by the event reception process during execution of the respective processes by the substrate processing device in accordance with the start timings of the respective processes calculated by the calculation processing process.
